(19) United States
(12) Patent Application Publication
(10) Pub. No.: US 2012/0212887 A1
(43) Pub. Date: Aug. 23, 2012

(54) LOCKING MODULE AND ELECTRONIC DEVICE USING THE SAME

(75) Inventor: Chang-An Chiang, New Taipei City (TW)

(73) Assignee: HANNSTAR DISPLAY CORPORATION, New Taipei City (TW)

(21) Appl. No.: 13/095,838

(22) Filed: Apr. 27, 2011

(30) Foreign Application Priority Data
Feb. 18, 2011 (TW) 100105502

(51) Int. Cl. H05K 7/00; F16B 17/00; H05K 5/02

(52) U.S. Cl. 361/679.01; 312/223.1; 403/381

(57) ABSTRACT

A locking module used for locking a component on a case of an electronic device is provided. The locking module includes a supporting member and a locking member. The supporting member is disposed on the case and has a rail. The locking member has a pressing portion and a pair of elastic arms extending from the pressing portion and opposite to each other. The elastic arms are slidably coupled to the rail, such that the locking member moves forward and backward between a first position and a second position. An electronic device is also provided.

### CROSS-REFERENCE TO RELATED APPLICATION

This application claims the priority benefit of Taiwan application serial no. 100105502, filed Feb. 18, 2011. The entirety of the above-mentioned patent application is hereby incorporated by reference herein and made a part of this specification.

### BACKGROUND OF THE INVENTION

1. Field of the Invention

The disclosure is related to a locking module, and in particular to a locking module which locks a component on an electronic device.

2. Description of Related Art

In the current age, technology and information are continuously being developed and advanced, and laptop computers are quite common and have become an indispensible type of electronic product in daily life or at work. A conventional keyboard of a laptop computer is locked on a case of the laptop computer through screws. This process is complex and poses great inconvenience both during locking and disassembly. In addition, repair or maintenance of other elements in the laptop computer, such as a hard drive, central processing unit, or other types of interface cards also require removal of the keyboard beforehand. If the keyboard is assembled by such a conventional method, inconvenience during repair is increased, wasting effort and time.

On the other hand, FIGS. 5A and 5B are schematic views showing assembly of a conventional laptop computer, whose keyboard may be assembled on the case of the laptop computer without screws. Please refer to FIGS. 5A and 5B. A laptop computer 200 includes a case 210 and a keyboard set 220 assembled on the case 210. Moreover, a side edge of the keyboard set 220 includes a plurality of grooves 222, and the case 210 includes a plurality of elastic hooks 212 which correspond to the grooves 222. The hooks 212 are correspondingly wedged into the grooves 222 to achieve the purpose of assembling the keyboard set 220 on the case 210.

It should be noted that the elastic hooks 212 are formed by way of forming broken holes 214 on the surface of the case 210. For a mold (not shown) used for injection-molding the case 210, the above is only achievable through introduction of a taper pin design and poses substantial difficulty and inconvenience to the size and product appearance of the case 210. On the other hand, when the keyboard set 220 is to be disassembled, a user must use one hand to use a tool to press the elastic hooks 212, so that the hooks are extracted from the grooves 222, and another hand must be used to remove the keyboard set 220, causing difficulty in user operation. In addition, the hooks 212 are located next to the broken holes 214 and are hence more fragile, so that they are easily damaged due to misuse of force during operation and by user inattention. In light of the above, the conventional laptop computer 200 poses obvious inconvenience and drawbacks during the assembly and disassembly of the keyboard set 220 thereof and thus must be improved.

### SUMMARY OF THE INVENTION

The disclosure is related to a locking module, so as to lock a component on a case of an electronic device.

The disclosure provides an electronic device which locks a component on a case thereof through a locking module.

An embodiment of the disclosure provides a locking module used to lock a component on a case of an electronic device. The locking module includes a supporting member and a locking member. The supporting member is disposed on the case and includes a rail. The locking member includes a first pressing portion and an elastic arm extending from the first pressing portion. The elastic arm is slidably coupled to the rail, such that the locking member moves between a first position and a second position.

An embodiment of the disclosure provides an electronic device which includes a case, a component, and a locking module. The case includes a housing area. The component is suitable for being assembled on the case to close the housing area. The component is used to limit the component to the housing area. The locking module includes a supporting member and a locking member. The supporting member is disposed on one of the case and the component and includes a rail. The locking member includes a first pressing portion and a pair of elastic arms extending from the pressing portion and opposite to each other. The elastic arms are slidably coupled to the rail, such that the locking member moves relative to the supporting member.

According to an embodiment of the disclosure, the locking member further includes a sunken portion located on the first pressing portion and opposite to the component. When the locking member is located at the first position, the sunken portion is exposed outside the case and the component.

According to an embodiment of the disclosure, the case includes a housing area facing the side edge of the component. The supporting member faces the housing area, so that the locking member passes through the housing area and presses the side edge of the component.

According to an embodiment of the disclosure, the supporting member further includes a first position-limiting portion located on the rail, and a terminal of each of the elastic arms includes a second position-limiting portion. The first position-limiting portion interferes with the second position-limiting portion and limits the locking member to the second position.

According to an embodiment of the disclosure, the locking module further includes an elastic member which is coupled between the locking member and the supporting member. The elastic member provides a force to drive the locking member to move from the second position towards the first position.

According to an embodiment of the disclosure, the component includes a second pressing portion, when the component is assembled on the case, the second pressing portion presses a side edge of the case and corresponds to the locking member.

According to an embodiment of the disclosure, the component is a keyboard set.

In light of the above, according to the embodiments of the disclosure, through the locking module disposed between the component and the case, after the component is disposed on the case, the locking member moves relative to the case, so that when the pressing member of the locking member is at the first position, the pressing portion presses the side edge of the component to achieve the effect of limiting the position of the component and fixing the component on the case by the locking module. Through such a simple structure, damage to the component during assembly is prevented, and it is more convenient to the user during subsequent disassembly and reassembly of the component.

In order to make the aforementioned and other objects, features and advantages of the disclosure comprehensible, embodiments accompanied with figures are described in detail below.

### BRIEF DESCRIPTION OF THE DRAWINGS

FIG. 1A is a schematic partial view of some components of an electronic device according to an embodiment of the disclosure.

FIG. 1B is a schematic partial view of the electronic device in FIG. 1A from another viewpoint.

FIGS. 2A and 2B are each a schematic exploded view of the electronic device in FIG. 1A from different viewpoints.

FIGS. 3A and 3B are each a schematic partial cross-sectional view of the electronic device in FIG. 1 after assembly.

FIGS. 3C and 3D are each a schematic partial bottom view of the electronic device in FIG. 1.

FIG. 4 is a schematic partial view of an electronic device according to another embodiment of the disclosure.

FIG. 5A is a schematic exploded view of a conventional electronic device.

FIG. 5B is a schematic exploded view of the electronic device in FIG. 5A from another viewpoint.

### DESCRIPTION OF EMBODIMENTS

The accompanying drawings constituting a part of this specification are incorporated herein to provide a further understanding of the invention. Here, the drawings illustrate embodiments of the invention and, together with the description, serve to explain the principles of the invention.

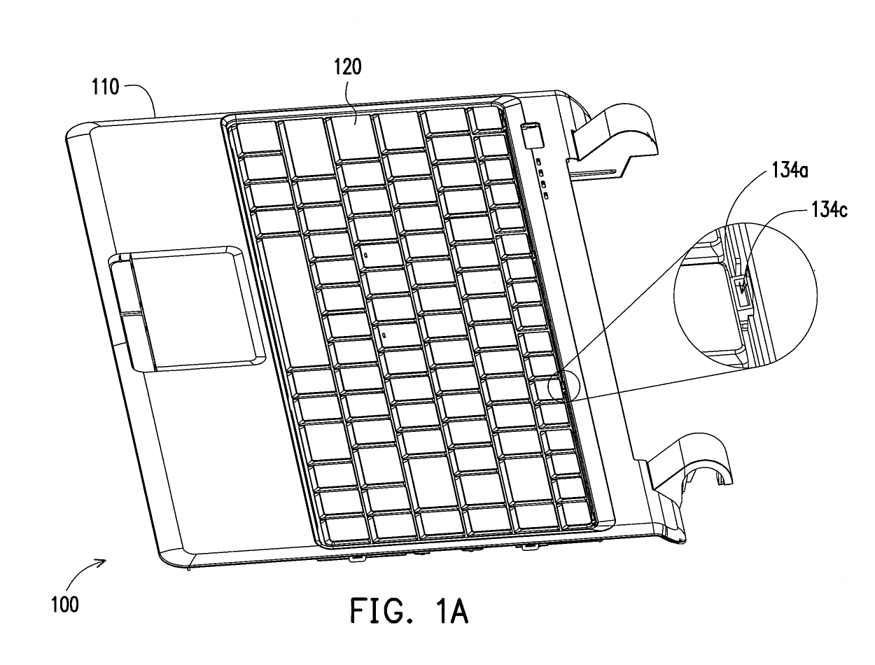

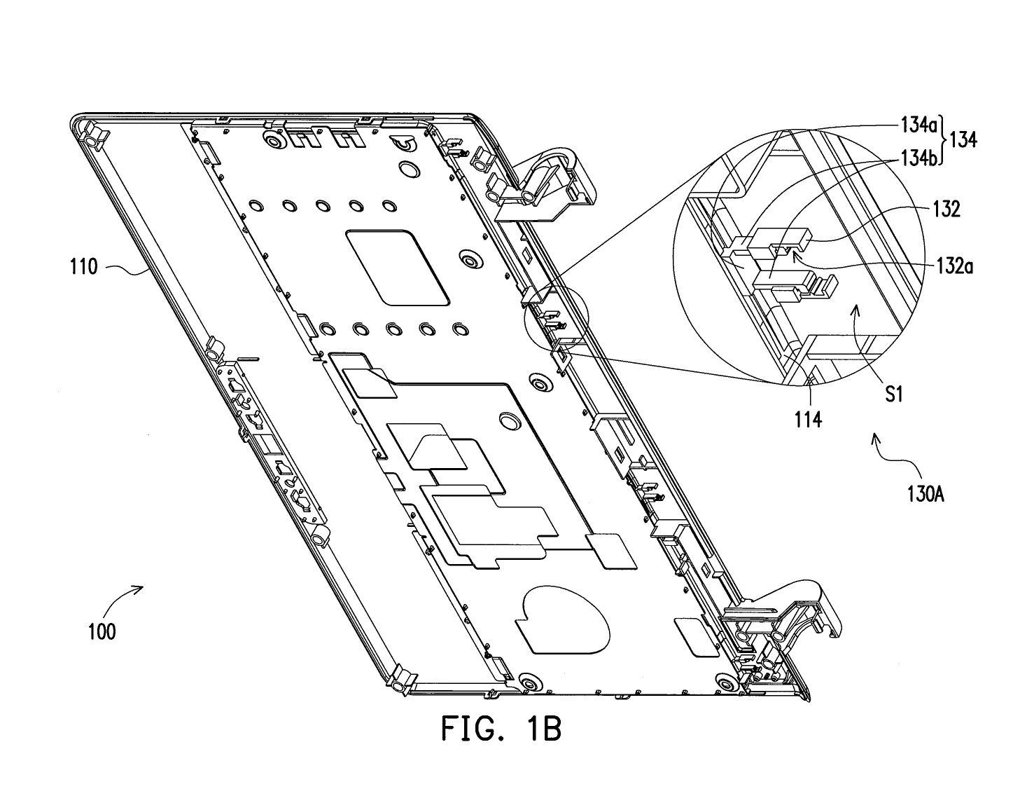

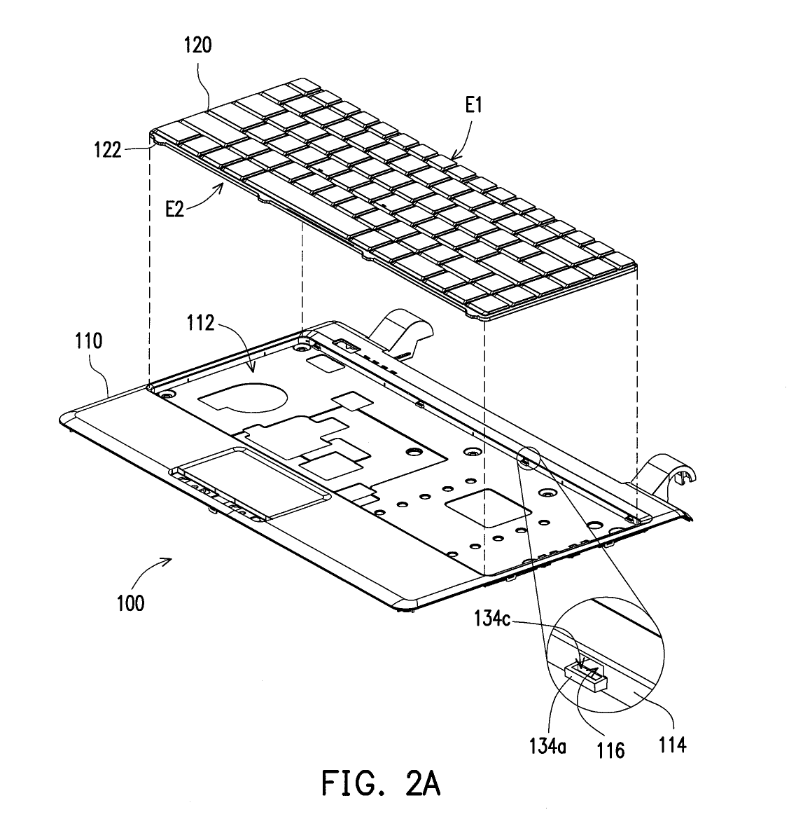

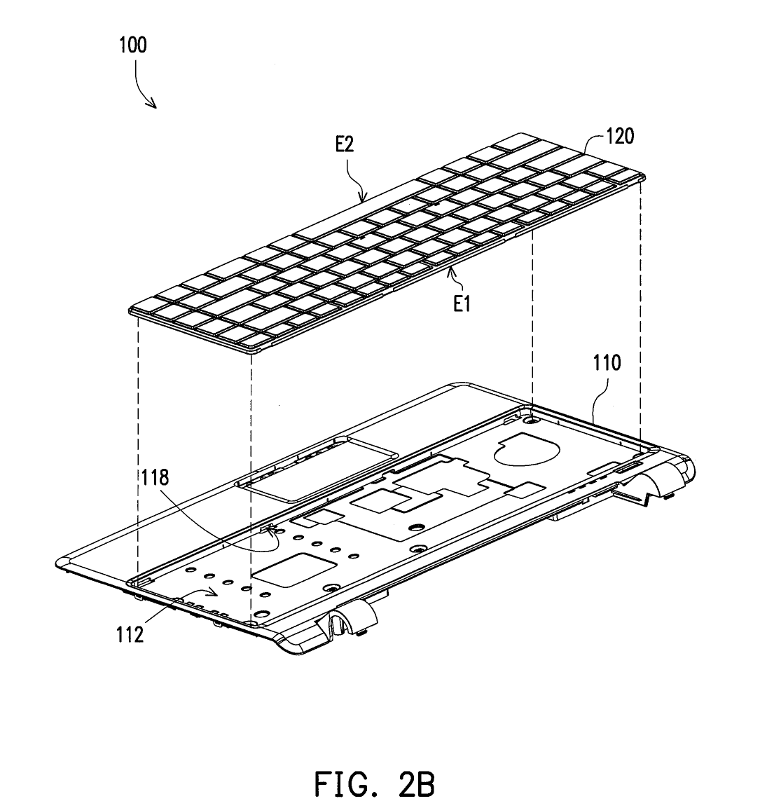

FIG. 1A is a schematic partial view of some components of an electronic device according to an embodiment of the disclosure. FIG. 1B is a schematic partial view of the electronic device in FIG. 1A from another viewpoint. FIGS. 2A and 2B are each a schematic exploded view of the electronic device in FIG. 1A from different viewpoints. Please refer to all of FIGS. 1A, 1B, 2A, and 2B. According to the present embodiment, an electronic device 100 is, for example, a laptop computer and includes a case 110, a component 120 assembled on the case 110, and a locking module 130A. The component 120 is, for example, a keyboard set, and the case 110 includes a housing area 112, so that the keyboard set is assembled in the housing area 112 of the case 110. In order that the keyboard set be easily detachable from the housing area 112 after being disposed in the housing area 112, the locking module 130A includes a supporting member 132 and a locking member 134. The supporting member 132 is disposed on the case 110 and includes a rail 132a. The locking member 134 includes a first pressing portion 134a and a pair of elastic arms 134b extending from the pressing portion 134a and opposite to each other. The elastic arms 134b are slidably coupled to the rail 132a, such that the locking member 134 moves relative to the case 110. When the component 120 is assembled on the case 110, the locking member 134 is movable relative to the case 110, so that the first pressing portion 134a presses the component 120 and thus limits a position of the component 120 and fixes the component 120 in the housing area 112 of the case 110. Although the above describes the pair of elastic arms 134b in a preferred embodiment, the disclosure is not limited to the above. Any element that is able to make the locking member move relative to the case and to achieve the structure of locking member 120 is suitable for the disclosure.

In light of the above, in the electronic device 100 according to the present embodiment, through the locking module 130A, the component 120 is assembled on the case 110 or is disassembled from the case 110. There is no need to worry about damaging the component 120 or the case 110 during assembly and disassembly, so that a user is able to smoothly assemble or disassemble the component 120 on the case 110 through such a simple structure.

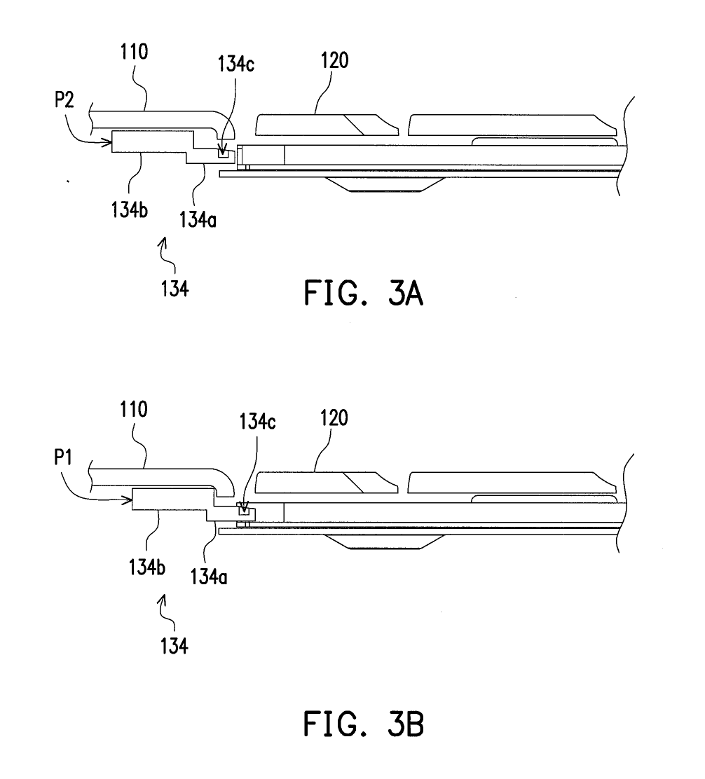

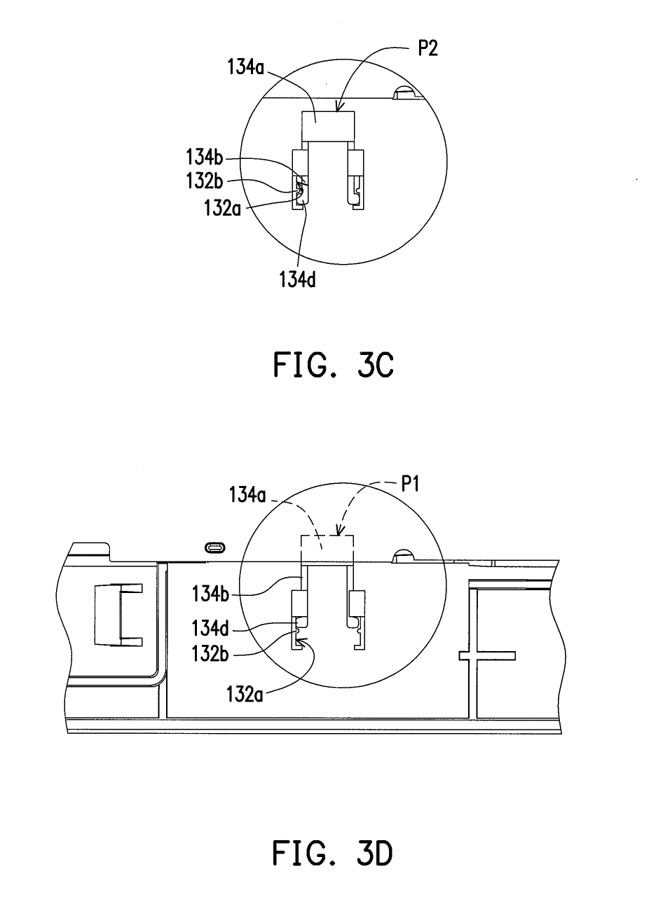

FIGS. 3A and 3B are each a schematic partial cross-sectional view of the electronic device in FIG. 1A after assembly. FIGS. 3C and 3D are each a schematic partial bottom view of the electronic device in FIG. 1, and FIGS. 3C and 3D correspond to a moving state of the locking member relative to the supporting member in FIGS. 3A and 3B, respectively. Different states of the locking member 134 moving relative to the case 110 before and after the component 120 is assembled are shown, so as to clearly distinguish relative relations between the elements. Please refer to FIGS. 1A, 1B, 2A, and 2B. In detail, the housing area 112 of the case 110 is a sunken structure, and the case 110 further includes an opening 116 at a sidewall 114 of the housing area 112. Moreover, please refer to both FIGS. 3A and 3D. The supporting member 132 is substantially disposed on a lower surface S1 of the case 110, and the supporting member 132 and the housing area 112 are located at two opposite sides of the sidewall 114 of the case 110. After the locking member 134 is disposed on the supporting member 132, the first pressing portion 134a of the locking member 134 directly faces the opening 116. Therefore, through cooperation between the elastic arm 134b and the rail 132a, the locking member 134 moves relative to the case 110 between a first position P1 and a second position P2. The first pressing portion 134a of the locking member 134 moves out from the opening 116 to the housing area 112, or moves from the housing area 112 into the case 110 through the opening 116.

In detail, please refer to FIGS. 1A, 1B, 2A, and 2B. In the electronic device 100 according to the present embodiment, the component 120 includes a plurality of second pressing portions 122 and a first side edge E1 and a second side edge E2 which are opposite to each other, wherein the second pressing portions 122 are disposed on the second side edge E2. On the other hand, the case 110 further includes a combining portion 118 disposed at a periphery of the housing area 112, and the second pressing portions 122 correspond to said combining portion 118. According to the present embodiment, each of the second pressing portions 122 is, for example, a tongue-shaped protrusion, and the combining portion 118 is a hole which corresponds to the tongue-shaped protrusion, so that the tongue-shaped protrusion correspondingly lodges into the hole. However, the type and number of the second pressing portions 122 and the combining portion 118 and the positions of the housing area at which the second pressing portions 122 and the combining portion 118 are disposed are not limited in the present embodiment.

When the component 120 (keyboard set) is to be assembled to the housing area 112 of the case 110, the second pressing portions 122 at the second side edge E2 correspondingly lodge into the combining portion 118 on the case 110. Next, when the component 120 is completely inserted into the housing area 112, the user is able to drive the locking member 134 to the first position P1, so that the first pressing portion 134a of the locking member 134 moves out from the opening 116 to the housing area 112 and presses the first side edge E1 of the component 120. Hence, the second pressing portions 122 located at the second side edge E2 of the component 120 press the combining portion 118 of the case 110, and the first side edge E1 of the component 120 is pressed by the first pressing portion 134a of the locking member 134, so that the position of the component 120 successfully limited and the component 120 is locked on the case 110 of the electronic device 100. On the other hand, when the user is to disassemble the component 120 from the case 110, only the locking member 134 is needed to be moved to the second position P2, so that the locking member 134 and the component 120 are relieved from a position-limiting state, and the component 120 is easily disassembled from the housing area 112.

It should be noted that the locking member 134 further includes a sunken portion 134c on the first pressing portion 134a. When the locking member 134 is located at the first position P1, the sunken portion 134c is substantially exposed outside the case 110 and the component 120. When the locking member 134 is located at the second position P2, the sunken portion 134c is located at the opening 116 and keeps a distance from an upper portion of the opening 116 (as shown by the partially magnified view in FIG. 2). In other words, according to the present embodiment, the user is able to use a tool (not shown) to extend to the locking member 134 between the component 120 and the case 110, and to press the sunken portion 134c with the tool to drive the locking member 134 to move between the first position P1 and the second position P2. Compared with conventional art, the above prevents damage to the component 120 and the case 110 and provides a structure that is easy to assemble and disassemble. However, the type of tool used to drive the locking member to move is not limited in the present embodiment.

On the other hand, the supporting member 132 according to the present embodiment further includes a first position-limiting portion 132b on the rail 132a, and a terminal of each of the elastic arms 134b includes a second position-limiting portion 134d, wherein the first position-limiting portion 132b is located on a path on which the elastic arms 134b slide relative to the rail 132a. Hence, the first position-limiting portion 132b interferes with the second position-limiting portion 134d and limits the locking member 134 to the second position P2. Moreover, when the user drives the locking member 134 to move to the first position P1, the first position-limiting portion 132b and the second position-limiting portion 134d interfere with each other and maintain the locking member 134 at the first position P1. Therefore, when the user disassembles the component, the locking member 134 is gradually moved to the required positions. Compared with conventional art which requires manual assembly and disassembly with both hands, the locking module 130A according to the present embodiment is more convenient.

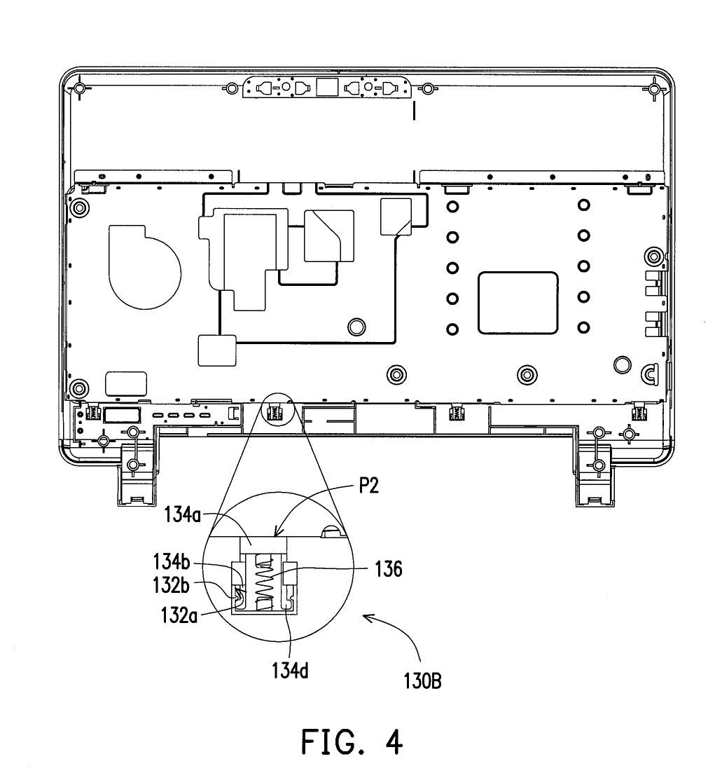

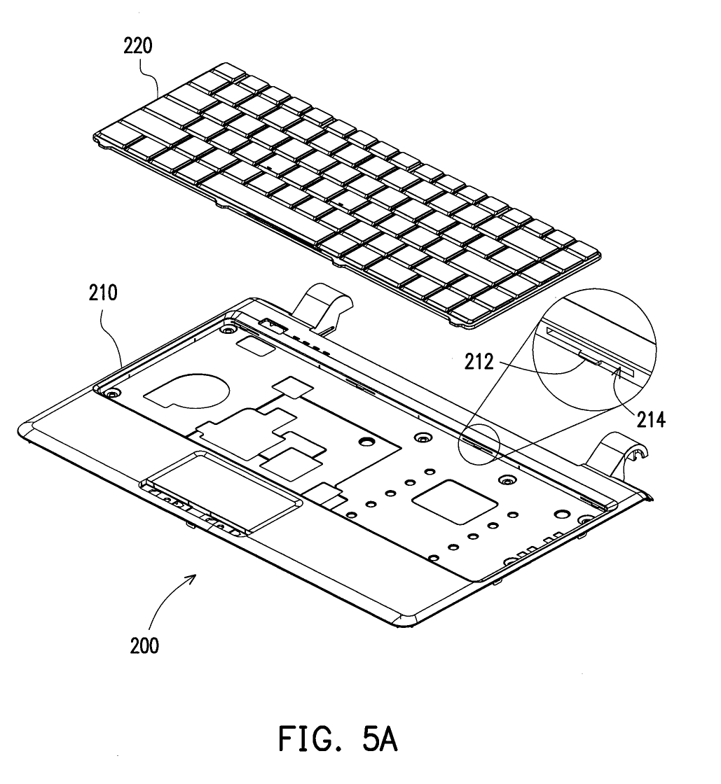

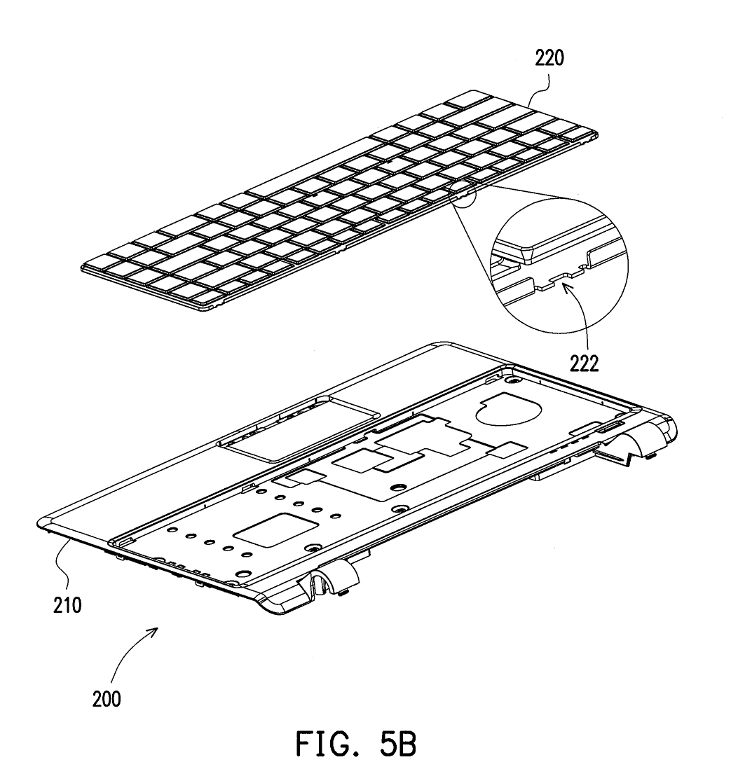

FIG. 4 is a schematic partial view of an electronic device according to another embodiment of the disclosure. Please refer to FIG. 4 in view of the embodiment shown in FIG. 1B. A difference between the present embodiment and the above embodiment is that a locking module 130B further includes an elastic member 136 which is connected between the locking member 134 and the supporting member 132, and the elastic member 136 is used to provide a force to drive the locking member 134 to move from the second position P2 towards the first position P1. This enables the user to drive the locking member 134 relative to the supporting member 132, and after the exerted force counters the interference state between the first position-limiting portion 132b and the second position-limiting portion 134c, the locking member 134 is able to move to the second position P2 through the elastic member 136, thereby requiring less force. However, the disclosure is not limited to the above configuration in the present embodiment. According to another embodiment not shown in the drawings, the elastic member 136 connected between the locking member 134 and the supporting member 132 may also provide a force to drive the locking member 134 to move from the first position P1 towards the second position P2. This adequately enables the user to exert less force during the disassembly of the component 120.

In addition, according to still another embodiment not shown in the drawings, the supporting member and locking member of the above locking module may also be disposed on the component and may be driven by a tool to move towards or away from the case, so that the component is locked on the case. Accordingly, any arrangement that generates a locking effect between the component and the case through the supporting member and movement relative to the supporting member is suitable for the disclosure.

In light of the above, according to the embodiments of the disclosure, through the locking module disposed between the component and the case, after the component is disposed on the case, the locking member moves relative to the case, so that when the locking member moves to the first position, the pressing portion thereof presses the side edge of the component to achieve the effect of limiting the position of the component by the locking module and fixing the component on the case. When the locking module moves to the second position, the component is correspondingly unlocked. Through such a simple structure, damage to the component during assembly is prevented, and it is more convenient to the user during subsequent disassembly and reassembly of the component.

It will be apparent to those skilled in the art that various modifications and variations can be made to the disclosure without departing from the scope or spirit of the disclosure. In view of the foregoing, it is intended that the disclosure cover modifications and variations of this disclosure provided they fall within the scope of the following claims and their equivalents.

What is claimed is:

1. A locking module, used to lock a component on a case of an electronic device, the locking module comprising:
a supporting member, disposed on the case and comprising a rail; and
a locking member, comprising a first pressing portion and an elastic arm extending from the first pressing portion, the elastic arm is slidably coupled to the rail, so that the locking member moves forward and backward between a first position and a second position.

2. The locking module as claimed in claim 1, wherein the locking member further comprises a sunken portion on the first pressing portion, when the locking member is located at the first position, the sunken portion is exposed outside the case and the component.

3. The locking module as claimed in claim 1, wherein the case comprises an opening which faces a side edge of the component, when the locking member is located at the first position, the first pressing portion passes through the opening and presses the side edge of the component.

4. The locking module as claimed in claim 1, wherein the supporting member comprises a first position-limiting portion on the rail, a terminal of the elastic arm comprises a second position-limiting portion, and the first position-limiting portion interferes with the second position-limiting portion to limit the locking member to the second position.

5. The locking module as claimed in claim 1, further comprising:
an elastic member, connected between the locking member and the supporting member, and the elastic member provides a force to drive the locking member to move from the second position towards the first position.

6. The locking module as claimed in claim 1, wherein the component comprises a second pressing portion, when the component is assembled to the case, the second pressing portion presses another side edge of the case which corresponds to the locking member.

7. An electronic device, comprising:
a case, comprising a housing area;
a component, suitable for being assembled on the case to cover the housing area;
a locking module, used to limit the component to the housing area, the locking module comprising:
a supporting member, disposed on one of the case and the component and comprising a rail; and
a locking member, comprising a first pressing portion and an elastic arm extending from the first pressing portion, the elastic arm is slidably coupled to the rail, so that the locking member moves forward and backward relative to the supporting member.

8. The electronic device as claimed in claim 7, wherein the component is a keyboard set.

9. The electronic device as claimed in claim 7, wherein the locking member further comprises a sunken portion on the first pressing portion, when the locking member is located at the first position, the sunken portion is exposed outside the case and the component.

10. The electronic device as claimed in claim 7, wherein the supporting member comprises a first position-limiting portion on the rail, a terminal of the elastic arm comprises a second position-limiting portion, and the first position-limiting portion interferes with the second position-limiting portion to limit the locking member to the second position.

11. The electronic device as claimed in claim 7, wherein locking module further comprises:
an elastic member, coupled between the locking member and the supporting member, and the elastic member provides a force to drive the locking member to move from the second position towards the first position.

12. The electronic device as claimed in claim 7, wherein the component comprises a second pressing portion, when the component is assembled to the housing area of the case, the second pressing portion presses another side edge of the case which corresponds to the locking member.
